(19) United States
(12) Patent Application Publication
(10) Pub. No.: US 2006/0243975 A1
(43) Pub. Date: Nov. 2, 2006

(54) Thin film transistor substrate, method of manufacturing the same and display apparatus having the same

(75) Inventors: Jang-Soo Kim, Suwon-si (KR); Sang-Woo Whangbo, Seoul (KR); Eou-Sik Cho, Seoul (KR); Shi-Yul Kim, Yongin-si (KR); Hwa-Yeul Oh, Seoul (KR); Chong-Chul Chai, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/361,804

(22) Filed: Feb. 24, 2006

(30) Foreign Application Priority Data
May 2, 2005 (KR) 2005-36821

(51) Int. Cl. H01L 29/04; G02F 1/1343

(52) U.S. Cl. 257/59; 257/72; 349/39; 349/43; 257/E29.273

(57) ABSTRACT

A thin film transistor substrate comprises an insulating substrate, a gate member formed on the insulating substrate, the gate member having a gate line and a first storage electrode spaced apart from the gate line, a gate insulating layer covering the gate member, an active layer formed on the gate insulating layer and overlapping the first storage electrode, and a data member formed on the active layer, the data member having a data line crossing the gate line and a second storage electrode overlapping the first storage electrode.

### CROSS-REFERENCE TO RELATED APPLICATION

This application claims priority to Korean Patent Application No. 2005-36821 filed on May 2, 2005, the disclosure of which is herein incorporated by reference in its entirety.

### BACKGROUND OF THE INVENTION

1. Technical Field

The present disclosure relates to a thin film transistor substrate, and more particularly, to a thin film transistor substrate having a storage capacitor in a metal-oxide-semiconductor (MOS) structure, a method of manufacturing the thin film transistor substrate and a display apparatus having the thin film transistor substrate.

2. Discussion of the Related Art

In general, a thin film transistor substrate is used for a circuit substrate to drive each of a plurality of pixels in a display apparatus such as, for example, a liquid crystal display apparatus and an organic electro luminescence apparatus.

The thin film transistor substrate is driven using a voltage charged in each of the pixels during one frame. The thin film transistor substrate uses a storage capacitor to maintain the charged voltage for one frame.

A structure of the thin film transistor substrate can be classified into an organic layer structure and a non-organic layer structure. The thin film transistor substrate of the organic layer structure employs an organic layer to planarize a surface of the thin film transistor substrate. The thin film transistor substrate of the non-organic layer structure does not include the organic layer. When the thin film transistor substrate of the non-organic layer structure is used, the storage capacitor is defined by a gate line and a pixel electrode.

However, when the storage capacitor for the thin film transistor substrate of the organic layer structure employs a same structure as the non-organic layer structure, a capacitance for the storage capacitor decreases since the organic layer functions as a dielectric substance. Thus, the storage capacitor defined by a gate line and a data line has been developed for the thin film transistor substrate of the organic layer structure.

When the thin film transistor substrate is manufactured using a five-mask process, the storage capacitor is readily formed. When the thin film transistor substrate is manufactured using a four-mask process where the data line and an active layer are patterned using a same mask, the active layer remains under the data line. As a result, the storage capacitor is formed in an MOS structure in the four-mask process.

A capacitance of the storage capacitor having the MOS structure varies according to a polarity of a voltage applied to the storage capacitor. As a result, a display defect such as, for example, a flicker occurs on a screen of the liquid crystal display apparatus due to a brightness difference between the pixels.

### SUMMARY OF THE INVENTION

Embodiments of the present invention provide a thin film transistor substrate capable of preventing a capacitance variation of a storage capacitor having an MOS structure to improve display quality, a method of manufacturing the thin film transistor substrate and a display apparatus having the thin film transistor substrate.

According to an embodiment of the present invention, a thin film transistor substrate comprises an insulating substrate, a gate member formed on the insulating substrate, the gate member having a gate line and a first storage electrode spaced apart from the gate line, a gate insulating layer to cover the gate member, an active layer formed on the gate insulating layer and overlapped with the first storage electrode, and a data member formed on the active layer, the data member having a data line crossing the gate line and a second storage electrode overlapped with the first storage electrode.

According to another embodiment of the present invention, a method of manufacturing a thin film transistor substrate comprises forming a gate member having gate lines and a first storage electrode disposed between the gate lines on an insulating substrate, forming a gate insulating layer on the insulating substrate to cover the gate member, forming an active layer on the gate insulating layer overlapping the first storage electrode, and forming a data member on the active layer, the data member having data lines crossing the gate lines and a second storage electrode overlapped with the first storage electrode.

According to another embodiment of the present invention, a display apparatus comprises a thin film transistor substrate, an opposite substrate and a liquid crystal layer. The thin film transistor comprises an insulating substrate, a gate member formed on the insulating substrate, the gate member having a gate line and a first storage electrode spaced apart from the gate line, a gate insulating layer to cover the gate member, an active layer formed on the gate insulating layer and at least overlapped with the first storage electrode, and a data member formed on the active layer. The data member has a data line crossing the gate line and a second storage electrode overlapped with the first storage electrode. The opposite substrate has a common electrode formed on a surface opposite to the thin film transistor substrate. The liquid crystal layer is formed between the thin film transistor and the opposite substrate.

The first storage electrode may have a smaller size than the active layer to expose an edge of the active layer.

The first storage electrode may have an opening through which the active layer is exposed.

The opening may have at least one of an I-shape, a cross shape or a circular shape.

The active layer may have a semiconductor layer and an ohmic contact layer, and a thickness of the gate insulating layer is equal to or greater than about three times a thickness of the semiconductor layer.

The gate insulating layer may have a thickness greater than about 4500 angstroms, and the semiconductor layer has a thickness equal to or less than about 1500 angstroms.

The active layer may comprise amorphous silicon.

The thin film transistor substrate may further comprise a passivation layer covering the data member, an organic layer formed on the passivation layer, and a pixel electrode formed on the organic layer, wherein the pixel electrode is electrically connected to the second storage electrode via a contact hole that is formed through the passivation layer and the organic layer.

### BRIEF DESCRIPTION OF THE DRAWINGS

Exemplary embodiments of the present invention can be understood in more detail from the following description taken in conjunction with the accompanying drawings in which:

FIG. 1 is a plan view showing a thin film transistor substrate according to an embodiment of the present invention;

FIG. 2 is a cross-sectional view taken along the line I-I′ in FIG. 1;

FIG. 3 is a cross-sectional view showing a thin film transistor substrate according to an embodiment of the present invention;

FIG. 4 is a plan view showing a first storage electrode in FIG. 3 according to an embodiment of the present invention;

FIG. 5 is a plan view showing a first storage electrode according to an embodiment of the present invention;

FIG. 6 is a plan view showing a first storage electrode according to an embodiment of the present invention;

FIG. 7 is a cross-sectional view showing a thin film transistor substrate according to an embodiment of the present invention;

FIG. 8 is a graph illustrating a capacitance of a storage capacitor in accordance with thickness variations of a gate insulating layer and a semiconductor layer in FIG. 7; and

FIG. 9 is a cross-sectional view showing a display apparatus according to an embodiment of the present invention.

### DESCRIPTION OF THE EXEMPLARY EMBODIMENTS

Exemplary embodiments of the present invention are more fully described below with reference to the accompanying drawings. The present invention may be embodied in many different forms and should not be construed as being limited to the embodiments set forth herein.

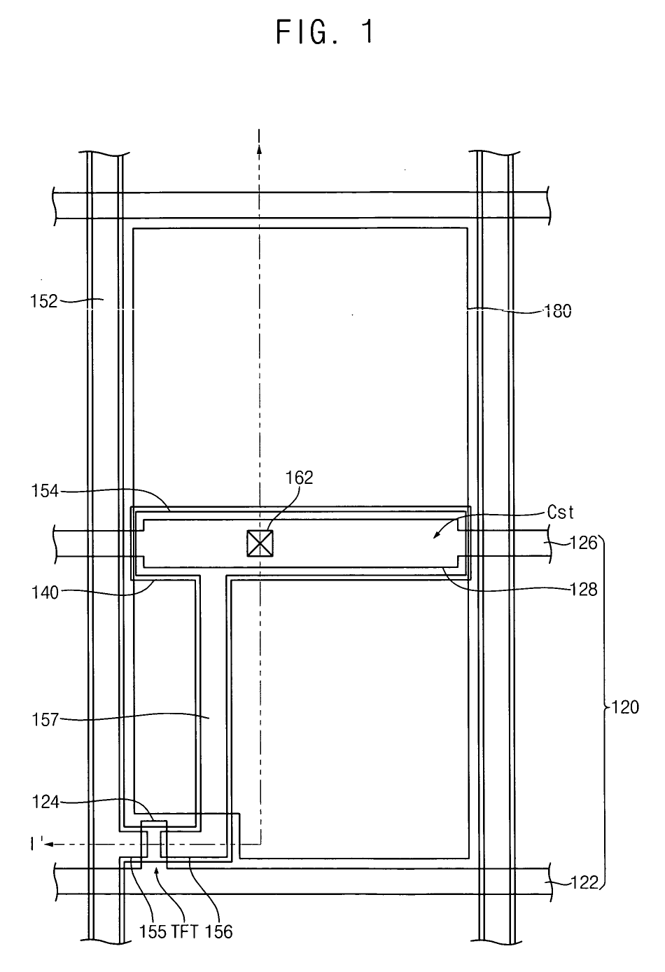

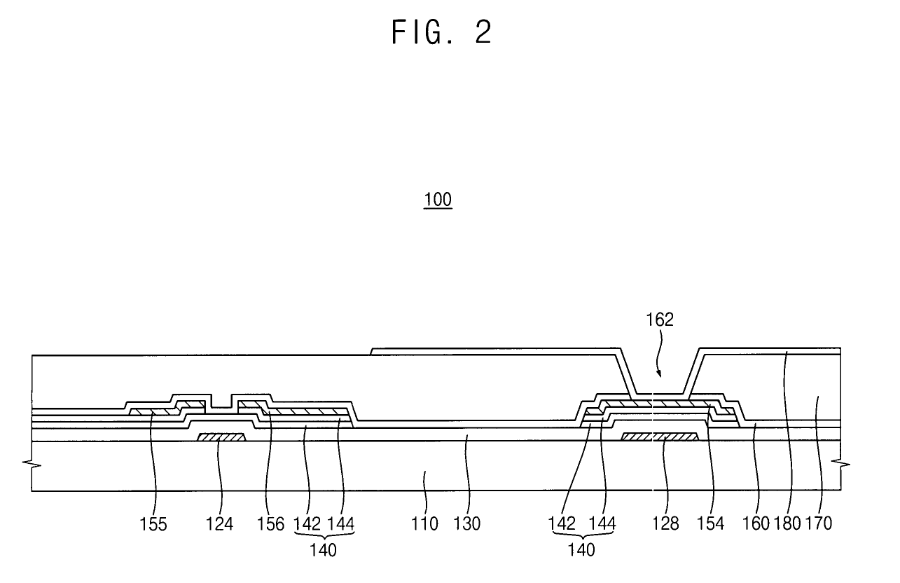

FIG. 1 is a plan view showing a thin film transistor substrate according to an embodiment of the present invention. FIG. 2 is a cross-sectional view of the thin film transistor substrate taken along the line I-I′ in FIG. 1.

Referring to FIGS. 1 and 2, a thin film transistor substrate 100 according to an embodiment of the present invention includes an insulating substrate 110, a gate member (or gate wiring) 120, a gate insulating layer 130, an active layer 140 and a data member (or data wiring) 150.

The insulating substrate 110 includes a transparent material to transmit light incident onto the insulating substrate 110. For example, the insulating substrate 110 includes glass.

The gate member 120 is formed on the insulating substrate 110 and includes a gate line 122 and a gate electrode 124 electrically connected to the gate line 122. The gate line 122 is extended in a horizontal direction. The gate electrode 124 forms a gate terminal of a thin film transistor (TFT).

The gate member 120 may further include a storage line 126 and a first storage electrode 128. The storage line 126 and the first storage electrode 128 are spaced apart from the gate line 122. The storage line 126 is extended in a substantially same direction as the gate line 122. The first storage electrode 128 is electrically connected to the storage line 126 and forms a lower electrode of a storage capacitor Cst. The storage line 126 and the first storage electrode 128 include a substantially same metal material as the gate line 122 and the gate electrode 124. In an embodiment of the present invention, the storage line 126 and the first storage electrode 128 are simultaneously formed with the gate line 122 and the gate electrode 124 via a photolithography process using a first mask.

The gate insulating layer 130 is formed on the insulating substrate 110 to cover the gate member 120. In an embodiment of the present invention, the gate insulating layer 130 includes, for example, a silicon nitride layer (SiNx) or a silicon oxide layer (SiOx).

The active layer 140 is formed on the gate insulating layer 130. The active layer 140 is overlapped with at least the gate electrode 124 and the first storage electrode 128. The active layer 140 includes a semiconductor layer 142 and an ohmic contact layer 144. In an embodiment of the present invention, the semiconductor layer 142 includes, for example, amorphous silicon (a-Si), and the ohmic contact layer 144 includes highly-doped n+amorphous silicon (n⁺ a-Si).

The data member 150 is formed on the active layer 140, and includes a data line 152 and a second storage electrode 154. The data line 152 extends in a vertical direction, and crosses the gate line 122. The second storage electrode 154 overlaps with the first storage electrode 128 and forms an upper electrode of the storage capacitor Cst.

The data member 150 may further include a source electrode 155, a drain electrode 156 and a connecting line 157. The source electrode 155 is electrically connected to the data line 152, and partially overlapped with the gate electrode 124. The drain electrode 156 is electrically connected to the second storage electrode 154 through the connecting line 157, and partially overlapped with the gate electrode 124. The source electrode 155 and the drain electrode 156 are spaced apart from each other, and the gate electrode 124 is disposed between the source and drain electrodes 155 and 156. The source electrode 155 forms a source terminal of the thin film transistor TFT, and the drain electrode 156 forms a drain terminal of the thin film transistor TFT.

The active layer 140 and the data member are formed in a photolithography process using a second mask. Therefore, the active layer 140 is formed under the data member, and the storage capacitor Cst has an MOS structure.

In an embodiment of the present invention, the first storage electrode 128 has a smaller size than the semiconductor layer 142 to expose an edge of the semiconductor layer 142. In general, when light is applied to the semiconductor layer 142 including a-Si, the semiconductor layer 142 generates a plurality of electrons and holes. When the electrons and holes move, the semiconductor layer 142 functions more like as a conductor than as a capacitor.

Therefore, the capacitance of the storage capacitor Cst is determined mainly by the gate insulating layer 130, and the capacitance of the storage capacitor Cst is constantly maintained regardless of a polarity of a voltage applied to the storage capacitor Cst. In an embodiment of the present invention, when an intensity of the light applied to the semiconductor layer 142 is enhanced or an exposed area of the semiconductor layer 142 increases, the capacitance of the storage capacitor Cst is efficiently controlled. In an embodiment of the present invention, a backlight assembly (not shown) disposed under the thin film transistor substrate 100 generates light having a uniform light intensity. Therefore, when the first storage electrode 128 has a smaller size than the semiconductor layer 142, the exposed area of the semiconductor layer 142 to which the light is applied may be increased, thereby maintaining the constant capacitance.

The thin film transistor substrate 100 may further include a passivation layer 160, an organic layer 170 and a pixel electrode 180.

The passivation layer 160 is formed on the insulating substrate 110 to cover the data member 150 and the gate insulating layer 130. In an embodiment of the present invention, the passivation layer 160 includes, for example, a silicon nitride layer (SiNx).

The organic layer 170 is formed on the passivation layer 160 to planarize a surface of the thin film transistor substrate 100.

A contact hole 162 is formed through the passivation layer 160 and the organic layer 170 via a photolithography process using a third mask.

The pixel electrode 180 is formed on the organic layer 170. The pixel electrode 180 includes a transparent conductive material to transmit light incident onto the pixel electrode 180. In an embodiment of the present invention, the pixel electrode 180 includes, for example, indium zinc oxide (IZO) or indium tin oxide (ITO). The pixel electrode 180 is electrically connected to the second storage electrode 154 through the contract hole 162 formed through the passivation layer 160 and the organic layer 170.

The pixel electrode 180 is patterned via a photolithography process using a fourth mask. An opening (not shown) may be formed through the pixel electrode 180 to divide the pixel electrode 180 defined by the gate line 122 and the data line 152 into a plurality of domains.

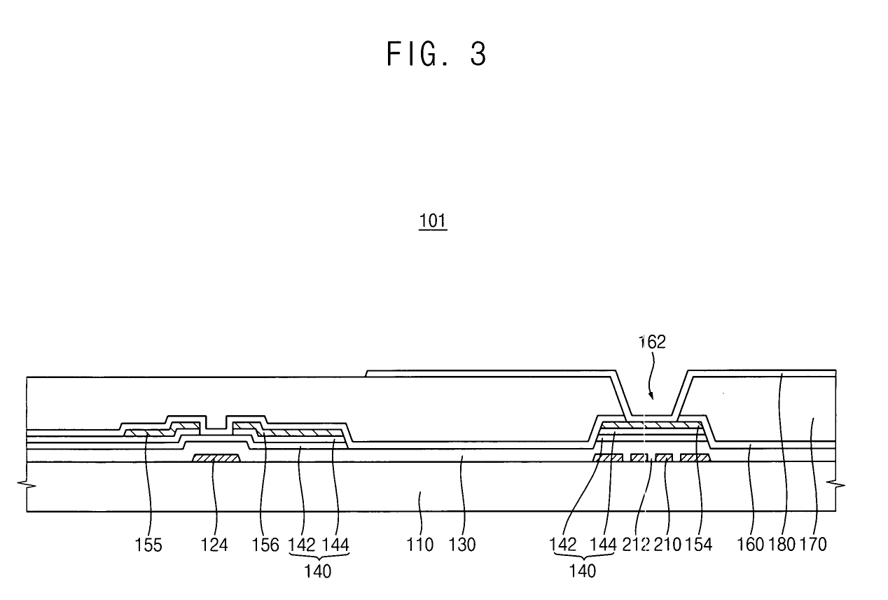

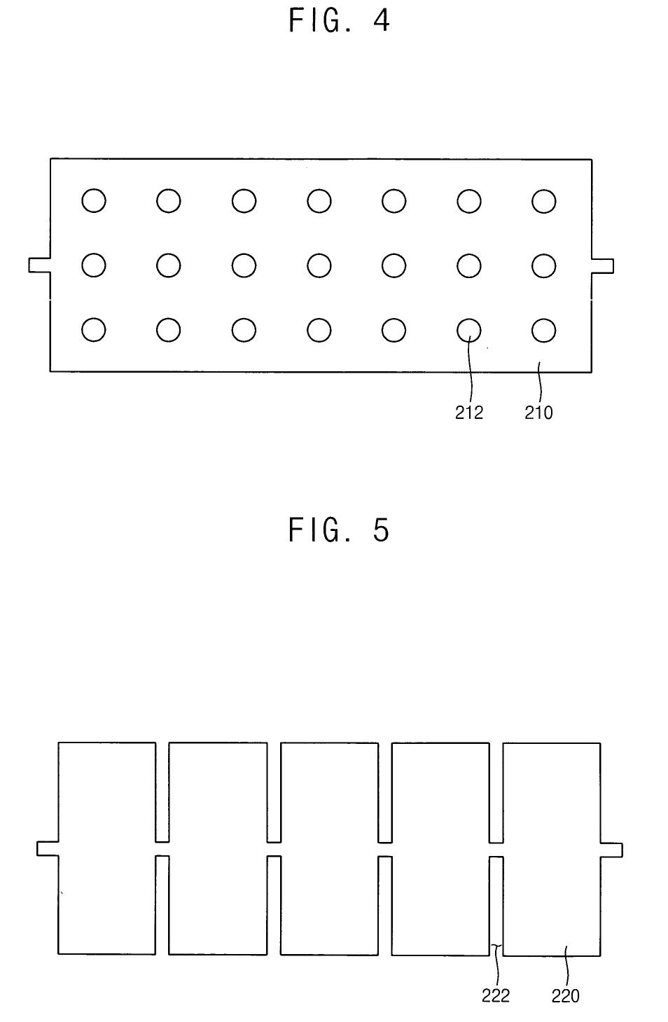

FIG. 3 is a cross-sectional view showing a thin film transistor substrate 101 according to another embodiment of the present invention. FIG. 4 is a plan view showing a first storage electrode in FIG. 3.

Referring to FIGS. 3 and 4, a first storage electrode 210 includes a plurality of openings 212 to expose the semiconductor layer 142. In an embodiment of the present invention, each of the plurality of openings 212 has a substantially circular shape. Alternatively, each of the plurality of openings 212 may have a polygonal shape. The first storage electrode 210 may have a larger size than the semiconductor layer 142 or a substantially same size as the semiconductor layer 142. Alternatively, the first storage electrode 210 may have a smaller size than the semiconductor layer 142 to expose an edge of the semiconductor layer 142.

When a size of each of the plurality of openings 212 increases, an amount of the light supplied to the semiconductor layer 142 increases. However, when the size of the opening 212 increases substantially, the storage capacitor Cst may not have a required capacitance since a size of the first storage electrode decreases. Therefore, the size of each of the plurality of openings 212 may be varied based on the required capacitance of the storage capacitor Cst.

FIG. 5 is a plan view showing a first storage electrode 220 according to another embodiment of the present invention.

Referring to FIGS. 3 and 5, a first storage electrode 220 includes a plurality of openings 222 to expose the semiconductor layer 142. In an embodiment of the present invention, each of the plurality of openings 222 has an I-shape. The plurality of openings 222 are formed by removing portions of the first storage electrode 220 from an edge portion of the first storage electrode 220 to a center portion of the first storage electrode 220. In an embodiment of the present invention, the first storage electrode 220 may have a larger size than the semiconductor layer 142 or a substantially same size as the semiconductor layer 142. Alternatively, the first storage electrode 220 may have a smaller size than the semiconductor layer 142 to expose an edge of the semiconductor layer 142.

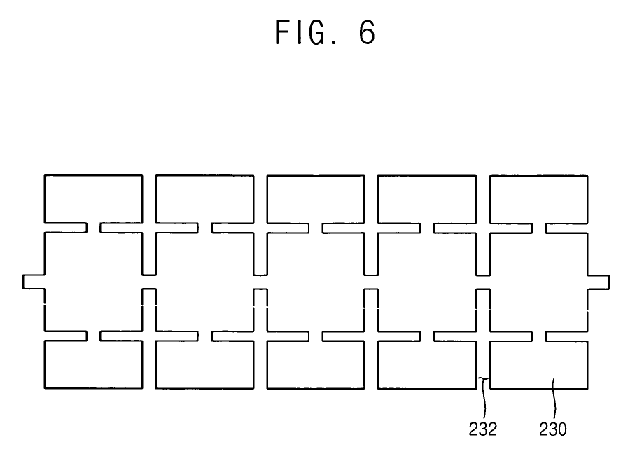

FIG. 6 is a plan view showing a first storage electrode 230 according to another embodiment of the present invention.

Referring to FIGS. 3 and 6, a first storage electrode 230 includes a plurality of openings 232 through which the semiconductor layer 142 is exposed. In an embodiment of the present invention, each of the plurality of openings 232 has a cross shape. In an embodiment of the present invention, the first storage electrode 230 may have a larger size than the semiconductor layer 142 or a substantially same size as the semiconductor layer 142. Alternatively, the first storage electrode 230 may have a smaller size than the semiconductor layer 142 to expose an edge of the semiconductor layer 142.

In alternate embodiments of the present invention, the openings formed in the first storage electrodes 210, 220 and 230 may be formed in various shapes other than those already described.

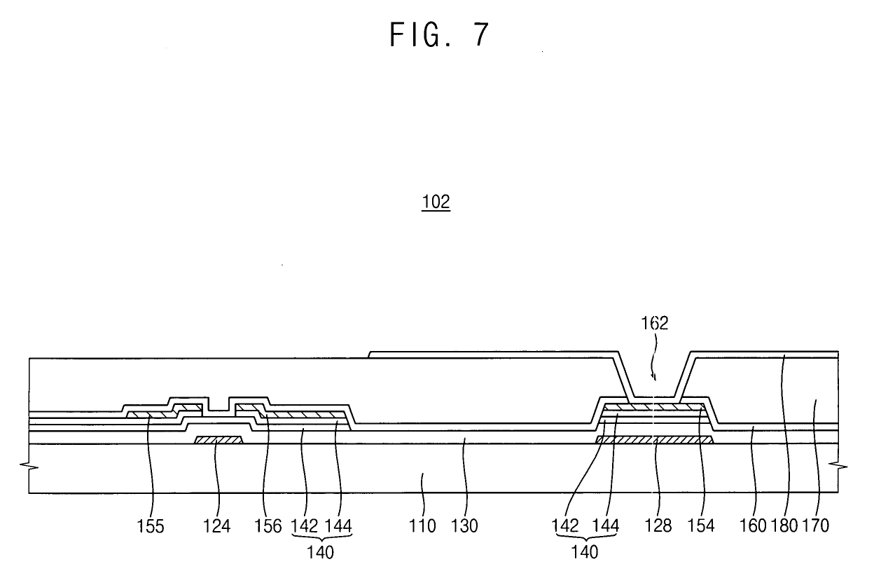

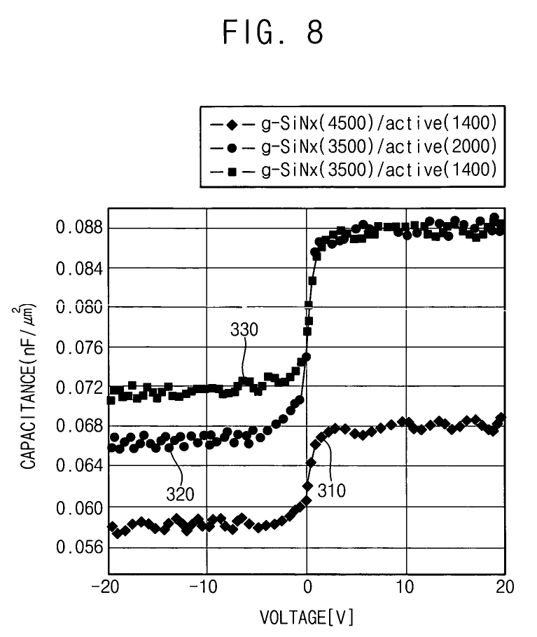

FIG. 7 is a cross-sectional view showing a thin film transistor substrate 102 according to another embodiment of the present invention. FIG. 8 is a graph illustrating a capacitance of a storage capacitor in accordance with thickness variations of the gate insulating layer 130 and the semiconductor layer 142 in FIG. 7.

Referring to FIG. 7, to reduce a variation of a capacitance according to a polarity of a voltage applied to the storage capacitor Cst, a thickness of the gate insulating layer 130 is equal to or greater than about three times a thickness of the semiconductor layer 142. In an embodiment of the present invention, the gate insulating layer 130 including the silicon nitride layer (SiNx) has a thickness of more than about 4500 angstroms, and the semiconductor layer 142 including the amorphous silicon (a-Si) has a thickness equal to or less than about 1500 angstroms.

In FIG. 8, a first graph 310 represents a capacitance of the storage capacitor Cst according to the Example, a second graph 320 represents a capacitance of the storage capacitor according to Comparative Example 1, and a third graph 330 represents a capacitance of the storage capacitor according to Comparative Example 2. In the Example, the gate insulating layer 130 has a thickness of about 4500 angstroms, and the semiconductor layer 142 has a thickness of about 1400 angstroms. In Comparative Example 1, the gate insulating layer 130 has a thickness of about 3500 angstroms, and the semiconductor layer 142 has a thickness of about 2000 angstroms. In Comparative Example 2, the gate insulating layer 130 has a thickness of about 3500 angstroms, and the semiconductor layer 142 has a thickness of about 1400 angstroms.

Referring to FIG. 8, the capacitance difference according to the polarity of the voltage in the Example has been represented as less than those in Comparative Examples 1 and 2. Therefore, when the thickness of the gate insulating layer 130 is equal to or greater than about three times the thickness of the semiconductor layer 142, the capacitance difference according to the polarity of the voltage may be reduced.

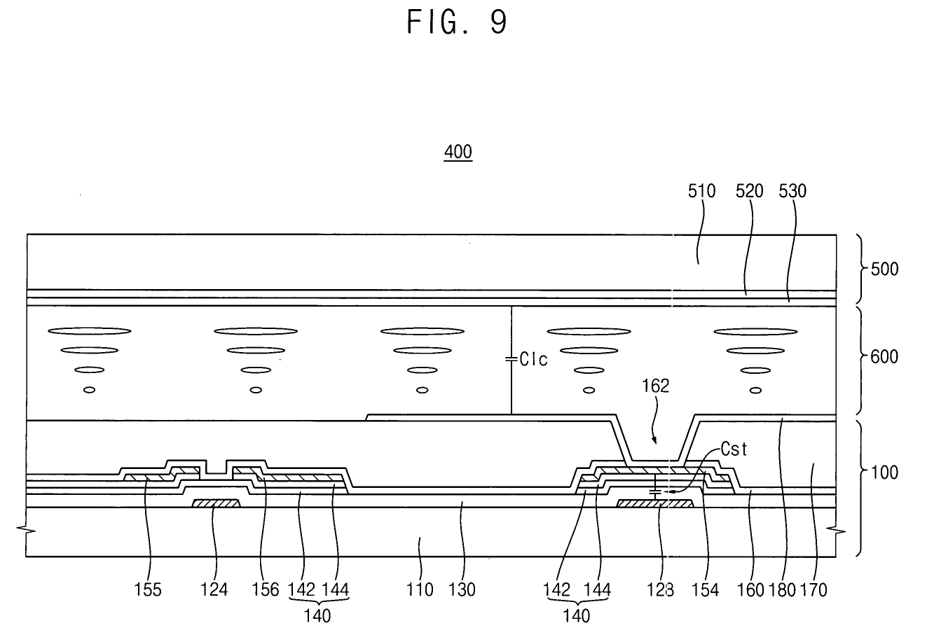

FIG. 9 is a cross-sectional view showing a display apparatus according to another embodiment of the present invention.

Referring to FIG. 9, a display apparatus 400 includes the thin film transistor substrate 100, an opposite substrate 500 and a liquid crystal layer 600.

The opposite substrate 500 is formed opposite to the thin film transistor substrate 100. The opposite substrate 500 includes a substrate 510, a color filter layer 520 and a common electrode 530.

The substrate 510 includes a transparent material to transmit light incident onto the substrate 510. In an embodiment of the present invention, the substrate 510 includes a substantially same material as an insulating substrate 110 of the thin film transistor substrate 100. For example, the substrate 510 comprises glass.

The color filter layer 520 includes a red color pixel, a green color pixel and a blue color pixel so as to display color images. Alternatively, the color filter layer 520 may be formed on the thin film transistor substrate 100.

The common electrode 530 is formed on a surface of the opposite substrate 500 opposite to the thin film transistor substrate 100. The common electrode 530 includes a substantially same transparent conductive material as the pixel electrode 180 of the thin film transistor substrate 100 to transmit light incident into the common electrode 530. Examples of the transparent conductive material for the common electrode 530 may include, for example, indium zinc oxide (IZO) and indium tin oxide (ITO).

The liquid crystal layer 600 is formed between the thin film transistor substrate 100 and the opposite substrate 500. The liquid crystal layer 600 includes a plurality of liquid crystal molecules having optical and electrical characteristics such as, for example, an anisotropic refractive index and an anisotropic dielectric constant. The alignment of the liquid crystal molecules is varied in response to an electric field applied between the pixel electrode 180 and the common electrode 530, thereby controlling a transmittance of light passing through the liquid crystal layer 600.

The display apparatus 400 includes a liquid crystal capacitor Clc defined by the pixel electrode 180, the liquid crystal layer 600 and the common electrode 530. The liquid crystal capacitor Clc is electrically connected to the storage capacitor Cst in parallel.

According to an embodiment of the present invention, the thin film transistor substrate has two storage capacitors having an MOS structure, and voltages having different polarities from each other are applied to the two storage capacitors Clc and Cst, respectively. Therefore, the capacitance variation may be compensated, and a flicker may be prevented. As a result, the display apparatus may have improved display quality.

Further, the thin film transistor substrate having an organic layer is manufactured via a four-mask process, thereby improving a productivity of the thin film transistor and reducing a manufacturing cost.

Although the exemplary embodiments of the present invention have been described with reference to the accompanying drawings, it is to be understood that the present invention should not be limited to these precise embodiments but various changes and modifications can be made by one ordinary skilled in the art without departing from the spirit and scope of the present invention. All such changes and modifications are intended to be included within the scope of the invention as defined by the appended claims.

What is claimed is:

1. A thin film transistor substrate comprising:
an insulating substrate;
a gate member formed on the insulating substrate, the gate member having a gate line and a first storage electrode spaced apart from the gate line;
a gate insulating layer covering the gate member;
an active layer formed on the gate insulating layer and overlapping the first storage electrode; and
a data member formed on the active layer, the data member having a data line crossing the gate line and a second storage electrode overlapping the first storage electrode.

2. The thin film transistor substrate of claim 1, wherein the first storage electrode has a smaller size than the active layer to expose an edge of the active layer.

3. The thin film transistor substrate of claim 1, wherein the first storage electrode has an opening through which the active layer is exposed.

4. The thin film transistor substrate of claim 3, wherein the opening has at least one of an I-shape, a cross shape or a circular shape.

5. The thin film transistor substrate of claim 1, wherein the active layer has a semiconductor layer and an ohmic contact layer, and a thickness of the gate insulating layer is equal to or greater than about three times a thickness of the semiconductor layer.

6. The thin film transistor of claim 5, wherein the gate insulating layer has a thickness greater than about 4500 angstroms, and the semiconductor layer has a thickness equal to or less than about 1500 angstroms.

7. The thin film transistor substrate of claim 1, wherein the active layer comprises amorphous silicon.

8. The thin film transistor substrate of claim 1, further comprising:
a passivation layer covering the data member;
an organic layer formed on the passivation layer; and
a pixel electrode formed on the organic layer,
wherein the pixel electrode is electrically connected to the second storage electrode via a contact hole that is formed through the passivation layer and the organic layer.

9. A method of manufacturing a thin film transistor substrate, the method comprising:
forming a gate member having gate lines and a first storage electrode disposed between the gate lines on an insulating substrate;
forming a gate insulating layer on the insulating substrate to cover the gate member;
forming an active layer on the gate insulating layer, the active layer overlapping the first storage electrode; and
forming a data member on the active layer, the data member having data lines crossing the gate lines and a second storage electrode overlapping the first storage electrode.

10. The method of claim 9, wherein the active layer has a larger size than the first storage electrode.

11. The method of claim 9, wherein the first storage electrode has an opening.

12. The method of claim 9, wherein the active layer has a semiconductor layer and an ohmic contact layer, and a thickness of the gate insulating layer is equal to or greater than three times a thickness of the semiconductor layer.

13. A display apparatus comprising:
a thin film transistor substrate comprising:
an insulating substrate;
a gate member formed on the insulating substrate, the gate member having a gate line and a first storage electrode spaced apart from the gate line;
a gate insulating layer covering the gate member;
an active layer formed on the gate insulating layer and overlapping the first storage electrode; and
a data member formed on the active layer, the data member having a data line crossing the gate line and a second storage electrode overlapping the first storage electrode,
an opposite substrate having a common electrode formed on a surface opposite to the thin film transistor substrate; and
a liquid crystal layer between the thin film transistor and the opposite substrate.

14. The display apparatus of claim 13. wherein the first storage electrode has a smaller size than the active layer to expose an edge of the active layer.

15. The display apparatus of claim 13, wherein the first storage electrode has an opening through which the active layer is exposed.

16. The display apparatus of claim 13, wherein the active layer has a semiconductor layer and an ohmic contact layer, and a thickness of the gate insulating layer is equal to or greater than about three times a thickness of the semiconductor layer.
